(19) United States
(12) Patent Application Publication
(10) Pub. No.: US 2026/0251409 A1
(43) Pub. Date: Aug. 27, 2026

(54) A THERMAL STRAP AND A METHOD FOR MANUFACTURING A THERMAL STRAP

(71) Applicant: TEKNOLOGIAN TUTKIMUSKESKUS VTT OY, Espoo (FI)

(72) Inventors: Shahin TABANDEH, Espoo (FI); Henrik SANDBERG, Espoo (FI); Richard HÖGSTRÖM, Espoo (FI)

(21) Appl. No.: 19/163,764

(22) PCT Filed: Nov. 1, 2023
(86) PCT No.: PCT/FI2023/050604

§ 371 Date: Sep. 9, 2025

(30) Foreign Application Priority Data
Mar. 9, 2023 (FI) 20235273

(51) Int. Cl. F28F 21/02

(52) U.S. Cl. CPC F28F 21/02; F28F 2255/02

(57) ABSTRACT

A thermal strap includes a graphene bundle part comprising a stack of graphene sheets, an encapsulation cover covering the graphene bundle part so that a first portion and a second portion of the graphene bundle part protrude outside the encapsulation cover, and a first end-fitting part having a first slot and a second end-fitting part having a second slot. The first portion of the graphene bundle part is attached inside the first slot of the first end-fitting part and the second portion of the graphene bundle part is attached inside the second slot of the second end-fitting part with a sealing so that the encapsulation cover extends partly inside the first slot of the first end-fitting part and the second slot of the second end-fitting part. A method for manufacturing a thermal strap enables optimizing a thermal contact at thermal interfaces of the thermal strap.

### CROSS-REFERENCE TO RELATED APPLICATIONS

The present application is a National Stage Application of PCT International Application No.: PCT/FI 2023/050604, filed on Nov. 1, 2023, which claims priority to Finnish Patent Application 20235273, filed in the Finnish Patent Office on Mar. 9, 2023, the disclosures of which are incorporated herein by reference in their entirety.

### TECHNICAL FIELD

The invention concerns in general the technical field of thermal straps. Especially the invention concerns graphene-based thermal straps.

### BACKGROUND

Thermal straps are used to transfer heat between two objects, e.g. between a heat source and a heat sink. Typically, the thermal straps comprise a substantially flexible middle part and a pair of rigid end-fitting parts attached at opposite ends of the middle part. The end-fitting parts enable connection of the thermal strap to the objects. The middle part may comprise a plurality of conductive wires or a stack of thermally conductive sheets. The plurality of wires and the sheets may be made of metallic material, e.g. aluminum or copper, or of non-metallic material, e.g. graphite, graphene or carbon fibers. The non-metallic material-based thermal straps have improved thermal properties when compared to the metallic material-based thermal straps. Furthermore, the non-metallic materials are more flexible than the metallic materials and thus provide improved flexibility of the thermal strap. Typically, thermal straps are used in space applications, in which mass of components is a crucial parameter. Thus, the mass reduction is a valuable benefit in the space applications. Minimizing the mass of the thermal strap enables to minimize the overall weight of a space vehicles and to reduce launching costs.

### SUMMARY

The following presents a simplified summary in order to provide basic understanding of some aspects of various invention embodiments. The summary is not an extensive overview of the invention. It is neither intended to identify key or critical elements of the invention nor to delineate the scope of the invention. The following summary merely presents some concepts of the invention in a simplified form as a prelude to a more detailed description of exemplifying embodiments of the invention.

An objective of the invention is to present a thermal strap and a method for manufacturing a thermal strap. Another objective of the invention is that the thermal strap and the method for manufacturing a thermal strap enable optimal thermal properties with reduced weight and particle contamination while maintaining high flexibility of the thermal strap.

The objectives of the invention are reached by a thermal strap and a method as defined by the respective independent claims.

According to a first aspect, a thermal strap is provided, wherein the thermal strap comprises: a graphene bundle part comprising a stack of graphene sheets, an encapsulation cover covering the graphene bundle part so that a first portion and a second portion of the graphene bundle part protrude outside the encapsulation cover, and a first end-fitting part comprising a first slot and a second end-fitting part comprising a second slot, wherein the first portion of the graphene bundle part is attached inside the first slot of the first end-fitting part and the second portion of the graphene bundle part is attached inside the second slot of the second end-fitting part with a sealing so that the encapsulation cover extends partly inside the first slot of the first end-fitting part and the second slot of the second end-fitting part.

The first portion of the graphene bundle part and the second portion of the graphene bundle part may reside at opposite ends of the graphene bundle part.

The first end-fitting part and the second end-fitting part may each comprise a main part and a secondary part, wherein the main part and the secondary part of the first end-fitting part may define together the first slot of the first end-fitting part, and wherein the main part and the secondary part of the second end-fitting part may define together the second slot of the second end-fitting part.

The first portion of the graphene bundle part may be sandwiched between the main part and the secondary part of the first end-fitting part and the second portion of the graphene bundle part may be sandwiched between the main part and the secondary part of the second end-fitting part.

The main part and the secondary part of the first end-fitting part may be attached together with at least one first pin having a respective alignment groove residing partly in the main part of the first end-fitting part and partly in the secondary part of the first end-fitting part, and the main part and the secondary part of the second end-fitting part may be attached together with at least one second pin having a respective alignment groove residing partly in the main part of the second end-fitting part and partly in the secondary part of the second end-fitting part.

The encapsulation cover may comprise a plurality of ventilation holes.

The plurality of ventilation holes may each comprises a filter structure.

The encapsulation cover may be sealed with an adhesive tape.

The material of the sealing may be thermally and/or electrically conductive.

The first portion of the graphene bundle part protruding through the first slot of the first end-fitting part and the second portion of the graphene bundle part protruding through the second slot of the second end-fitting part may form thermal interfaces of the thermal strap.

According to a second aspect, a method for manufacturing a thermal strap is provided, wherein the method comprises: forming a graphene bundle part comprising a stack of graphene sheets, providing an encapsulation cover to cover the graphene bundle part so that a first portion and a second portion of the graphene bundle part protrude outside the encapsulation cover, and attaching the first portion of the graphene bundle part inside a first slot of a first end-fitting part and the second portion of the graphene bundle part inside a second slot of a second end-fitting part with a sealing so that the encapsulation cover extends partly inside the first slot of the first end-fitting part and the second slot of the second end-fitting part.

The providing the encapsulation cover to cover the graphene bundle part may comprise enveloping the encapsulation cover around the graphene bundle part or slipping the encapsulation cover around the graphene bundle part.

The first portion of the graphene bundle part and the second portion of the graphene bundle part may reside at opposite ends of the graphene bundle part.

The first end-fitting part and the second end-fitting part may comprise a main part and a secondary part, wherein the main part and the secondary part of the first end-fitting part may define together the first slot of the first end-fitting part, and wherein the main part and the secondary part of the second end-fitting part may define together the second slot of the second end-fitting part.

The attaching of the first portion of the graphene bundle part inside the first slot of the first end-fitting part may comprise sandwiching the first portion of the graphene bundle part between the main part and the secondary part of the first end-fitting part, and the attaching of the second portion of the graphene bundle part inside the second slot of the second end-fitting part may comprise sandwiching the second portion of the graphene bundle part between the main part and the secondary part of the second end-fitting part.

The method may further comprise: attaching the main part and the secondary part of the first end-fitting part together with at least one first pin having a respective alignment groove residing partly in the main part of the first end-fitting part and partly in the secondary part of the first end-fitting part, and attaching the main part and the secondary part of the second end-fitting part together with at least one second pin having a respective alignment groove residing partly in the main part of the second end-fitting part and partly in the secondary part of the second end-fitting part.

Alternatively or in addition, the method may further comprise perforating the encapsulation cover to provide a plurality of ventilation holes.

The plurality of ventilation holes may each comprise a filter structure.

Alternatively or in addition, the method may further comprise sealing the encapsulation cover with an adhesive tape.

The material of the sealing may be thermally and/or electrically conductive.

The first portion of the graphene bundle part protruding through the first slot of the first end-fitting part and the second portion of the graphene bundle part protruding through the second slot of the second end-fitting part may form thermal interfaces of the thermal strap.

Various exemplifying and non-limiting embodiments of the invention both as to constructions and to methods of operation, together with additional objects and advantages thereof, will be best understood from the following description of specific exemplifying and non-limiting embodiments when read in connection with the accompanying drawings.

The verbs “to comprise” and “to include” are used in this document as open limitations that neither exclude nor require the existence of unrecited features. The features recited in dependent claims are mutually freely combinable unless otherwise explicitly stated. Furthermore, it is to be understood that the use of “a” or “an”, i.e. a singular form, throughout this document does not exclude a plurality.

### BRIEF DESCRIPTION OF FIGURES

The embodiments of the invention are illustrated by way of example, and not by way of limitation, in the figures of the accompanying drawings.

FIGS. 1A and 1B illustrate schematically an example of a thermal strap.

FIG. 2A illustrates schematically an example of a stack of graphene sheets forming a graphene bundle part.

FIGS. 2B and 2C illustrate schematically an example of a graphene bundle part covered by an encapsulation cover.

FIG. 2D illustrates schematically an example of the thermal strap with an encapsulation cover comprising a plurality of ventilation holes.

FIGS. 2E and 2F illustrate schematically an example of a ventilation hole comprising a filter structure.

FIG. 3 illustrates schematically an example of a thermal strap comprising a non-symmetrical graphene bundle part.

FIG. 4A illustrates schematically an example of an end-fitting part.

FIG. 4B illustrates schematically a cross-sectional view of a first end-fitting part, wherein a first portion of the graphene bundle part is attached inside a first slot of the first end-fitting part.

FIG. 4C illustrates schematically an example of a first end-fitting part comprising a main part and a secondary part.

FIG. 4D illustrates schematically an example of a second end-fitting part comprising a main part and the secondary part.

FIG. 5 illustrates schematically an example of a method for manufacturing a thermal strap.

### DESCRIPTION OF THE EXEMPLIFYING EMBODIMENTS

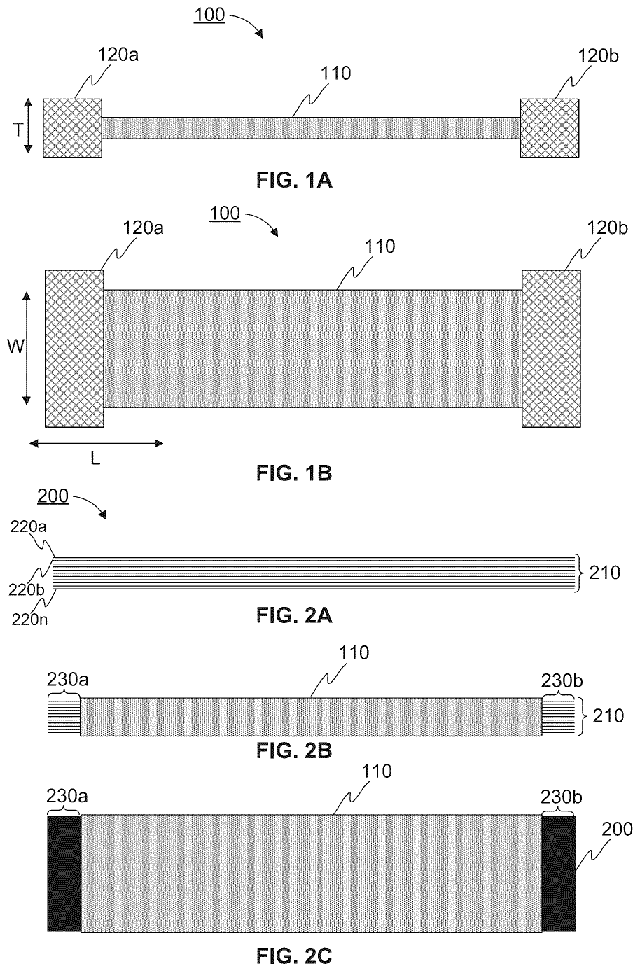

FIGS. 1A and 1B illustrate schematically an example of a thermal strap 100. FIG. 1A illustrates a side view of the example thermal strap 100. FIG. 1B illustrates a top view of the example thermal strap 100. The thermal strap 100 comprises a graphene bundle part 200, an encapsulation cover 110, a first end-fitting part 120a, and a second end-fitting part 120b. For sake of clarity the graphene bundle part 200 is not shown in FIGS. 1A and 1B. The thermal strap 100 may be used in different applications. Preferably, the thermal strap 100 may be used in space applications, e.g. a thermal management of a space device or system, but the thermal strap 100 may also be used in non-space applications, e.g. for a thermal management of a non-space device or a system. Some non-limiting examples of the applications of the thermal strap 100 may comprise, but is not limited to, dilution refrigerators, cryocoolers, stored cryogens, cold boxes, cryomodules, superconducting components (e.g. magnets and electronics), detectors, sensors, infrared systems, X-ray systems, focal planes, thermal switches, optical systems, stored cryogens, star trackers, telescopes, electronic boxes, microwave antennas, radiators, laser-pointing systems, pho-tonics, cryocooler compressors, battery cooling, medical instruments, heat pipe connections, etc. The dimensions of the thermal strap 100 may be optimized, i.e. scaled, individually for each application of the thermal strap 100. In addition, the material(s) of the end-fitting parts 120a, 120b of the thermal strap 100 may be optimized, i.e. selected, individually for each application of the thermal strap 100. The thickness direction T of the thermal strap 100 is illustrated in FIG. 1A, while the width direction W and the length direction L of the thermal strap 100 are illustrated in FIG. 1B. The end-fitting parts 120a, 120b enable a mechanical connection of the thermal strap 100 to terminals to which the thermal strap 100 is intended to be connected. In other words, the end-fitting parts 120a, 120b form mechanical interfaces for mechanically connecting the thermal strap 100 to the terminals of the apparatus according to the application. From now on throughout this application the term “terminals” is used to mean the terminals to which the thermal strap 100 is intended to be connected, i.e. the terminals of a device or a system according to the application of the thermal strap 100.

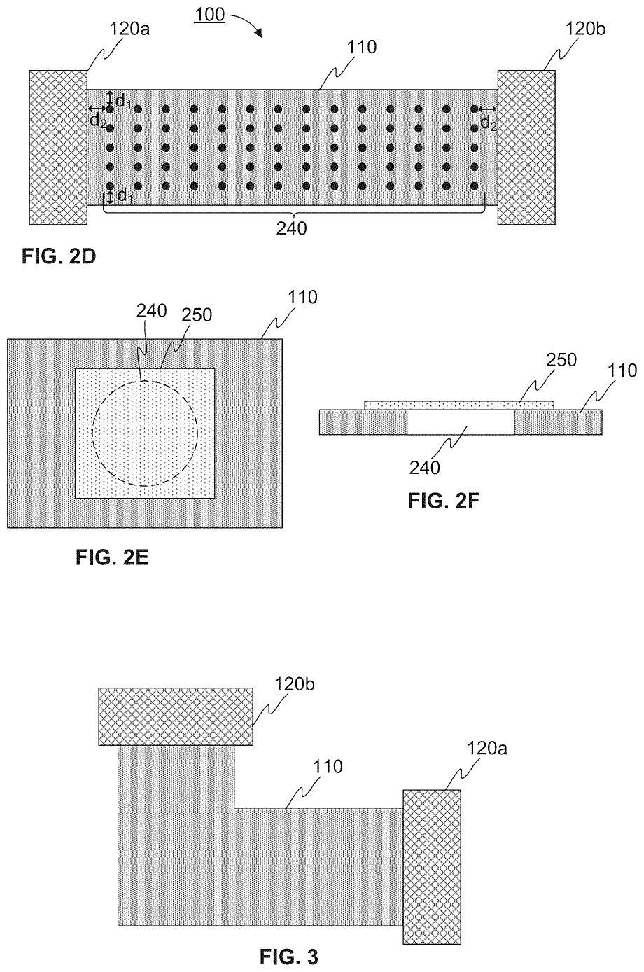

The graphene bundle part 200 comprises a stack 210 of graphene sheets 220a-220n. In other words, the graphene bundle part 200 is formed by the stack 210 of a plurality of graphene sheets 220a-220n. FIG. 2A illustrates schematically an example of the stack 210 of graphene sheets 220a-220n forming the graphene bundle part 200. FIG. 2A illustrates a side view of the graphene bundle part 200. The number of graphene sheets 220a-220n of the graphene bundle part 200 depends on a desired thermal conduction of the thermal strap 100 depending on the application of the thermal strap 100. For example, the number of the graphene sheets 220a-220n of the graphene bundle part 200 may be between 100 and 120 depending on the application of the thermal strap 100. Similarly, dimensions of the graphene bundle part 200, e.g. the thickness, the width, and the length of the graphene bundle part 200, depend on the application of the thermal strap 100. In other words, the dimensions of the graphene bundle part 200 may be optimized for each application of the thermal strap 100. The dimensions of the graphene bundle part 200 may be considered also as determining factors for the number of the graphene sheets 220a-220n of the graphene bundle part 200, because increase or decrease in length, thickness, and/or width of the graphene bundle part 200 has an effect on the number of the graphene sheets 220a-220n required to achieve the desired thermal conduction. Naturally, also the thickness of individual graphene sheets 220a-220n and conductance may have an effect on the number of the graphene sheets 220a-220n. For example, in a non-limiting detector application example of the thermal strap 100, the number of the graphene sheets 220 a-220n in the graphene bundle part 200 may be 120, the thickness of each graphene sheet 220 a-220n may be 25 micrometres, the thickness of the graphene bundle part 200 may be 3.5 millimetres, the width of the graphene bundle part 200 may be 40 millimetres, and the length of the graphene bundle part 200 may be 95 millimetres.

The encapsulation cover 110 covers the graphene bundle part 200 so that a first portion 230a of the graphene bundle part 200 and a second portion 230b of the graphene bundle part 200 protrude outside the encapsulation cover 110. In other words, the first portion 230a of the graphene part 200 and the second part 230b of the graphene bundle are not enveloped by the encapsulation cover 110. The encapsulation cover 110 is configured to capture particles that detach from one or more graphene sheets 220a-220n of the graphene bundle part 200, i.e. graphene sheet particles. In other words, the encapsulation cover 110 inhibits graphene sheet particle release. Without the encapsulation cover 110 the graphene sheet particles may release into a clean environment of the apparatus comprising the thermal strap 100. FIGS. 2B and 2C illustrate schematically an example of the graphene bundle part 200 covered by the encapsulation cover 110. FIG. 2B illustrates a side view of the graphene bundle part 200 covered with the encapsulation cover 110. FIG. 2C illustrates a top view of the graphene bundle part 200 covered with the encapsulation cover 110. The encapsulation cover 110 may for example be made of a metallized polyimide (PI) film or a metallized Mylar film. The encapsulation cover 110 may also be made of any other encapsulation material having required electrical conductivity. The metallized PI or Mylar film is applied with the metallized face outward, i.e. not towards the graphene bundle part 200. The encapsulation cover 110 comprises at least one film layer. The encapsulation cover 110 may be sealed with an adhesive tape. A non-limiting example of the adhesive tape for sealing the encapsulation cover 110 may be COOLCAT B R50 adhesive tape, which is certified for space applications.

The encapsulation cover 110 may comprise a plurality of ventilation holes 240. The ventilation holes 240 allow air to vent out from inside the encapsulation cover 110 (i.e. from the graphene bundle part 200), but do not allow graphene sheet particles to pass through the encapsulation cover 110. The plurality of ventilation holes 240 are spaced apart from each other. In other words, each ventilation hole is a distance away from the adjacent ventilation hole(s). The distance between the adjacent ventilation holes 240 may for example depend on the dimensions of the encapsulation cover 110 as well as on the number of the ventilation holes 240 required for sufficient venting. The dimension of each ventilation hole of the plurality of ventilation holes 240 of the encapsulation cover 110 may be between 20 to 100 micrometers. The plurality of ventilation holes 240 may reside on flat areas of the encapsulation cover 110, because the ventilation holes 240 on the edges of the stack 210 of the graphene sheets 220a-220n of the graphene bundle part 200 may act as starting points for fractures of the encapsulation cover 110. The plurality of ventilation holes 240 may reside on the flat areas of the encapsulation cover 110 a first distance di from the edges of the stack 210 of the graphene sheets 220a-220n, when the graphene bundle part 200 is encapsulated with the encapsulation cover 110, to further prevent fractures of the encapsulation cover 110. Alternatively or in addition, the plurality of ventilation holes 240 may reside on the flat areas of the encapsulation cover 110 a second distance de from the end-fitting parts 120a, 120b, when the encapsulated graphene bundle part 200 is attached to the end-fitting parts 120a, 120b as will be described. The flat areas of the encapsulation cover 110 are the areas of the encapsulation cover facing towards the outer surface of the topmost graphene sheet 220a of the stack 210 and the outer surface of the bottommost graphene sheet 220n of the stack 210. FIG. 2D illustrates schematically an example of the thermal strap 100 with the encapsulation cover 110 comprising the plurality of ventilation holes 240. FIG. 2D illustrates a top view of the thermal strap 100. In the top view of the thermal strap 100 the flat area of the encapsulation cover 110 facing towards the outer surface of the topmost graphene sheet 220a of the stack 210, i.e. the flat surface of the encapsulation cover 110 on which at least part of the ventilation holes 240 may be formed, is shown. Similarly, in a bottom view of the thermal strap 100, the flat area of the encapsulation cover 110 facing towards the outer surface of the bottommost graphene sheet 220n of the stack 210 would be shown. The plurality of ventilation holes 240 may for example be substantially in an organized form, e.g. in a grid form as in the example of FIG. 2D. The grid form enables easy manufacturing of the plurality of ventilation holes 240. Alternatively, the plurality of ventilation holes 240 may be in a disorganized form, i.e. in an arbitrary form. According to an example, one or more ventilation holes of the plurality of ventilation holes 240 may comprise a filter structure 250. Preferably, each ventilation hole of the plurality of ventilation holes 240 of the encapsulation cover 110 may comprise the filter structure 250. The filter structure 250 may be formed by adding filter material to a region on the encapsulation cover 110 around each ventilation hole 240 comprising the filter structure 250. The filter structure(s) 250 increases the efficiency of the inhibition of the graphene sheet particle release by the encapsulation cover 110. The filter material may for example be a HEPA filter, an aerosol sampling filter (e.g. a fiber filter or a membrane filter), or a metal mesh filter (e.g. a sintered metal filter). The pore size of the filter material may depend on the application of the thermal strap 100. FIGS. 2E and 2F illustrate schematically an example of one ventilation hole 240 comprising the filter structure 250. FIG. 2E illustrates a top view of the ventilation hole 240 with the filter structure 250. FIG. 2F illustrates a cross sectional view of the ventilation hole 240 with the filter structure 250.

The graphene bundle part 200 may preferably be symmetrical as illustrated in FIGS. 2A-2D. When the graphene bundle part 200 is symmetrical, the first portion 230a of the graphene bundle part 200 and the second portion 230b of the graphene bundle part 200 reside at opposite ends of the graphene bundle part 200 as illustrated for example in FIGS. 2B and 2C. The symmetrical graphene bundle part 200 may preferably be substantially rectangular as illustrated for example in FIG. 2C. However, the graphene bundle part 200 may also have any other shape, either symmetrical or non-symmetrical. FIG. 3 illustrates a non-limiting example of a thermal strap 100 comprising a non-symmetrical graphene bundle part 110. FIG. 3 illustrates a top view of thermal strap 100 with the non-symmetrical graphene bundle part 200. In the example of FIG. 3 the non-symmetrical graphene bundle part 200 is substantially L-shaped.

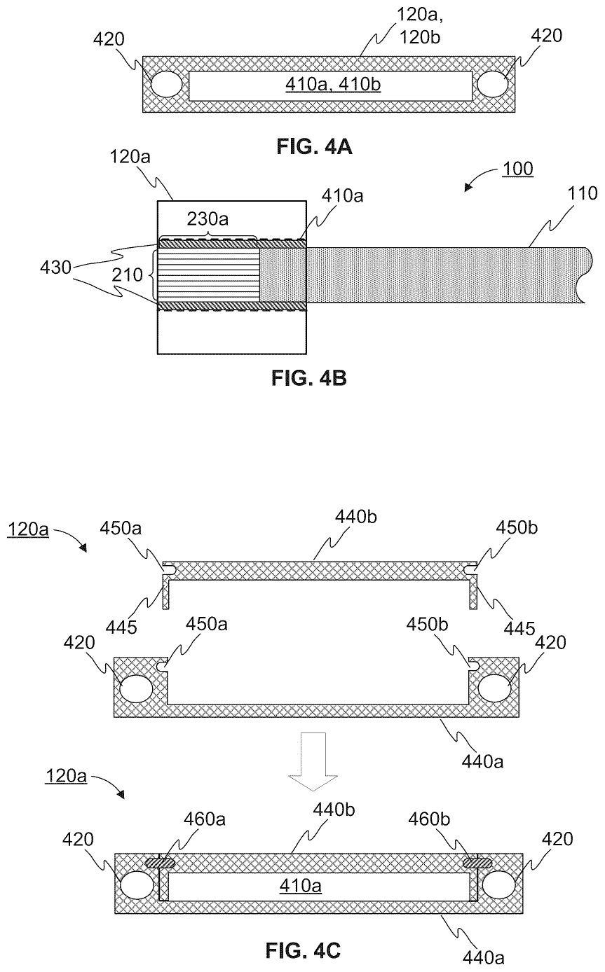

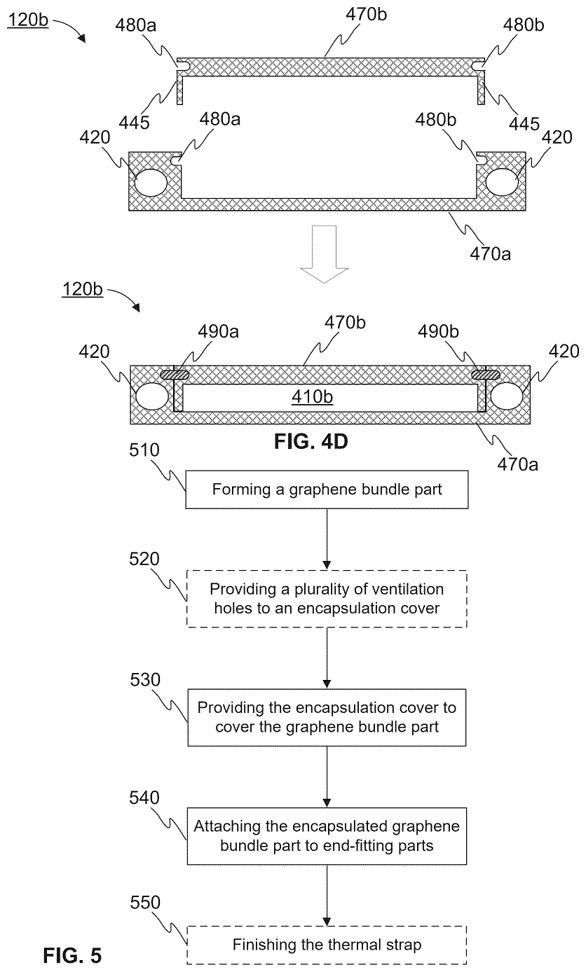

The first end-fitting part 120a comprises a first slot 410a. The second end-fitting part 120b comprises a second slot 410b. Preferably, the first end-fitting part 120a and the second end-fitting part 120b are substantially identical to each other. FIG. 4A illustrates schematically an example of an end-fitting part 120a, 120b. FIG. 4A illustrates a front view of the end-fitting part 120a, 120b. The end-fitting part 120a, 120b of the example of FIG. 4A may be the first end-fitting part 120a or the second end-fitting part 120b. The dimensions of the end-fitting parts 120a, 120b, i.e. the thickness, the width, and the length of the end-fitting parts 120a, 120b, may depend on the application of the thermal strap 100. In other words, the dimensions of the end-fitting parts 120a, 120b may be optimized, i.e. scaled, for each application of the thermal strap 100. For example, in the non-limiting detector application example of the thermal strap 100 mentioned above, the thickness of the end-fitting parts 120 a, 120 b may be 8 millimetres, the width of the end-fitting parts 120 a, 120 b may be 10 millimetres, and the length of the end-fitting parts 120 a, 120 b may be 60 millimetres. The first end-fitting part 120a and the second end-fitting part 120b may be made of the same material. Alternatively, the first end-fitting part 120a may be made of different material than the second end-fitting part 120b. The end-fitting parts 120a, 120n are the main contributors to the weight of the thermal strap 100, therefore the material(s) of the end-fitting parts 120a, 120b may preferably be metal having a low density. Moreover, the material(s) of the end-fitting parts 120a, 120b may depend on the application of the thermal strap 100. For example, the material of each end-fitting part 120a, 120b may be selected so that the thermal expansion of said end-fitting part 120a, 120b matches with the terminals. For example, in the non-limiting detector application example of the thermal strap 100 mentioned above, the material of the first end-fitting part 120a may be aluminium and the material of the second end-fitting part 120b may be Molybdenum or vice versa, i.e. the material of the first end-fitting part 120a may be molybdenum and the material of the second end-fitting part 120b may be aluminium or vice versa, depending on which end-fitting part 120a, 120b is attached to which terminal of the detector. The end fitting part 120a, 120b may further comprise coupling holes 420 for coupling devices, e.g. screw or bolts, etc., (not shown in FIG. 4A) used to mechanically fix the end-fitting parts 120a, 120b to the terminals. Preferably, each end-fitting part 120a, 120b comprises two coupling holes 420 as illustrated in the example of FIG. 4A, but the number of the coupling holes 420 in each end-fitting part 120a, 120b is not limited to two.

The first portion 230a of the graphene bundle part 200 is attached inside the first slot 410a of the first end-fitting part 120a and the second portion 230b of the graphene bundle part 200 is attached inside the second slot 410b of the second end-fitting part 120b with a sealing 430 so that the encapsulation cover 110 extends partly inside the first slot 410a of the first end-fitting part 120a and the second slot 410b of the second end-fitting part 120b. The first portion 230a of the graphene bundle part 200 and the second portion 230b of the graphene bundle part 200 are not in a direct contact with the respective end-fitting parts 120a, 120b due to the sealing 430. The first portion 230a of the graphene bundle part 200 protruding through the first slot 410a of the first end-fitting part 120a and the second portion 230b of the graphene bundle part 200 protruding through the second slot 410b of the second end-fitting part 120b form thermal interfaces of the thermal strap 100 for thermally connecting the thermal strap 100 to the terminals. This enables that the thermal properties of the thermal strap 100 are not affected by the thermal interfaces. It also enables optimizing thermal contact at the thermal interfaces of the thermal strap 100, where the thermal strap 100 interacts with the terminals. FIG. 4B illustrates schematically a cross-sectional view of the first end-fitting part 120a which illustrates the first portion 230a of the graphene bundle part 200 attached inside the first slot 410a of the first end-fitting part 120a with the sealing 430 so that the encapsulation cover 110 extends partly inside the first slot 410a of the first end-fitting part 120a. The second portion 230b of the graphene bundle part 200 is attached similarly inside the second slot 410b of the second end-fitting part 120b with the sealing 430 so that the encapsulation cover 110 extends partly inside the second slot 410b of the second end-fitting part 120b, but for sake of clarity not shown in FIG. 4B. The sealing 430 is applied to the inside of the slots 410a, 410b of the end-fitting parts 120a, 120b so that voids after inserting the portions 230a, 230b of the graphene bundle part 200 inside the respective slots 410a, 410b of the end-fitting parts 120a, 120b are filled with the sealing 430. In addition to the attaching function of the sealing 430, the sealing 430 also acts to close the encapsulation cover 110 to further inhibit particle release. To be able to close the encapsulation cover 110 by the sealing 430, the encapsulation cover 110 needs to extends partly inside the first slot 410a of the first end-fitting part 120a and partly inside the second slot 410b of the second end-fitting part 120b. The material of the sealing 430 may be thermally and/or electrically conductive. When the material of the sealing 430 is thermally conductive, the sealing 430 also serves to improve thermal contact between the parts of the thermal strap 100. However, the thermal conductance of the sealing 430 is not critical for the overall thermal conductance of the thermal strap 100. The material of the sealing 430 may for example comprise adhesive or soft metal. A non-limiting example of thermally and electrically conducting adhesive for the sealing 430 may be Masterbond EP3HTSDA-2, which is also certified for space applications. The soft metal may for example be indium, tin, or gold.

The first end-fitting part 120a may comprise a main part 440a and a secondary part 440b. Similarly, and second end-fitting part 120b may comprise a main part 470a and a secondary part 470b. The main part 440a and the secondary part 440b of the first end-fitting part 120a define together the first slot 410a of the first end-fitting part 120a. The main part 470a and the secondary part 470b of the second end-fitting part 120b define together the second slot 410b of the second end-fitting part 120b. The attachment of the first portion 230a of the graphene bundle part 200 inside the first slot 410a of the first end-fitting part 120a may comprise that the first portion 230a of the graphene bundle part 200 is sandwiched between the main part 440a and the secondary part 440b of the first end-fitting part 120a. Similarly, the attachment of the second portion 230b of the graphene bundle part 200 inside the second slot 410b of the second end-fitting part 120b may comprise that the second portion 230b of the graphene bundle part 200 is sandwiched between the main part 470a and the secondary part 470b of the second end-fitting part 120b. As described above the graphene bundle part 200 is attached inside the slots 410a, 410b of the end-fitting parts 120a, 120b with the sealing 430. When the adhesive is used as the sealing 430, the adhesive may further act to attach the main parts 440a, 470a and the respective secondary parts 440b, 470b of the end-fitting parts 120a, 120b together. The secondary part 440b, 470b of each end-fitting part 120a, 120b may comprise wings 445 to improve accommodation of the encapsulated graphene bundle part 200 inside the slots 410a, 410b of the end-fitting parts 120a, 120b. The wings 445 are arranged at the ends of the respective secondary part 440b, 470b in the width direction W of the thermal strap 100. The wings 445 of the secondary part 440b, 470b are engaged in the forming of the respective slot 410a, 410b of the respective end-fitting part 120a, 120b.

The main part 440a and the secondary part 440b of the first end-fitting part 120a may be attached together with at least one first pin 460a, 460b having a respective alignment groove 450a, 450b residing partly in the main part 440a of the first end-fitting part 120a and partly in the secondary part 440b of the first end-fitting part 120a. Similarly, the main part 470a and the secondary part 470b of the second end-fitting part 120b may be attached together with at least one second pin 490a, 490b having a respective alignment groove 480a, 480b residing partly in the main part 470a of the second end-fitting 120b part and partly in the secondary part 470b of the second end-fitting part 120b. In addition to the attaching the main part 440a, 470a together with the respective secondary part 440b, 470b, the at least one first pin 460a, 460b and the at least one second pin 490a, 490b improve also the attachment of the encapsulated graphene bundle part 200 to the first end-fitting part 120a and to the second end-fitting part 120b. Preferably, the main part 440a and the secondary part 440b of the first end-fitting part 120a are attached together with two first pins 460a, 460b having respective two alignment grooves 450a, 450b residing partly in the main part 440a of the first end-fitting part 120a and partly in the secondary part 440b of the first end-fitting part 120a. Similarly, preferably the main part 470a and the secondary part 470b of the second end-fitting part 120b are attached together with two second pins 490a, 490b having respective two alignment grooves 480a, 480b residing partly in the main part 470a of the second end-fitting 120b part and partly in the secondary part 470b of the second end-fitting part 120b. However, the attaching of the main part 440a, 470a together with the respective secondary part 440b, 470b may also be realized with one first pin 460a having the respective alignment groove 450a and with one second pin 490a having the respective alignment groove 480a or with more than two first pins 460a, 460b having the respective alignment grooves 450a, 450b and with more than two second pins 490a, 490b having the respective alignment grooves 480a, 480b. Using two pins 460a, 460b, 490a, 490b to attach the main part 440a, 470a together with the respective secondary part 440b, 470b improves the attachment in comparison of using only one pin 460 a, 490a per end-fitting part 120 a, 120 b and simplifies the design and manufacturing of the end-fitting parts 120a, 120b in comparison of using only one pin 460 a, 490 or more than two pins 460 a, 460 b, 490 a, 490b per end-fitting part 120 a, 120b. The use of the at least one pin 460a, 460b, 490a, 490b, preferably two pins 460a, 460b, 490a, 490b, to attach the main part 440a, 470a together with the respective secondary part 440b, 470b, enable reducing the size of the end-fitting parts 120a, 120b, which in turn enable reducing the weight of the end-fitting parts 120a, 120b and also the total weight of the thermal strap 100. The reduced weight of the thermal strap 100, in turn, reduces the launching costs. According to a non-limiting example, in the non-limiting detector application example of the thermal strap 100 mentioned above, the weight of the thermal strap 100 is 62.3 g. An adhesive may be added into the alignment groove(s) 450a, 450b, 480a, 480b, to secure the placement of the pin(s) 460a, 460b, 490a, 490b. The adhesive may for example be thermally and/or electrically conductive. The electrical conductivity of the adhesive ensures for example that the encapsulation cover 110 does not get electrically charged and cause sparks or discharge. For space applications a NASA certified adhesive may be used. The material of the at least one first pin 460a, 460b and the at least one second pin 490a, 490b may for example be aluminium.

FIG. 4C illustrates schematically an example of the first end-fitting part 120a comprising the main part 440a and the secondary part 440b. The upper part of FIG. 4C illustrates the main part 440a and the secondary part 440b of the first end-fitting part 120a apart from each other, i.e. unattached. The lower part of FIG. 4C illustrates the main part 440a and the secondary part 440b of the first end-fitting part 120a attached together with two first pins 460a, 460b having two respective alignment grooves 450a, 450b residing partly in the main part 440a of the first end-fitting part 120a and partly in the secondary part 440b of the first end-fitting part 120a. FIG. 4D illustrates schematically an example of the second end-fitting part 120b comprising the main part 470a and the secondary part 470b. The upper part of FIG. 4D illustrates the main part 470a and the secondary part 470b of the second end-fitting part 120b apart from each other, i.e. unattached. The lower part of FIG. 4D illustrates the main part 470a and the secondary part 470b of the second end-fitting part 120b attached together with two second pins 490a, 490b having two respective alignment grooves 480a, 480b residing partly in the main part 470a of the second end-fitting part 120b and partly in the secondary part 470b of the second end-fitting part 120b.

Next a method for manufacturing the thermal strap 100 described above is discussed refer-ring to FIG. 5, which illustrates the method for manufacturing the thermal strap 100 as a flow chart.

At a step 510, the graphene bundle part 200 comprising the stack 210 of graphene sheets 220a-220n is formed. The forming of the graphene bundle part 200 may comprise for example cutting the graphene sheets 220a-220n into the desired geometrical shape depending on the application of the thermal strap 100 and stacking a number of graphene sheets 220a-220n required to reach the desired thermal conduction of the thermal strap 100 depending on the application of the thermal strap 100 to form the graphene bundle part 200.

At a step 530, the encapsulation cover 110 is provided to cover the graphene bundle part 200 formed at the step 510 so that the first portion 230a of the graphene bundle part 200 and the second portion 230b of the graphene bundle part 200 protrude outside the encapsulation cover 110. The providing the encapsulation cover 110 to cover the graphene bundle part 200 may comprise enveloping the encapsulation cover 110 around the graphene bundle part 200. Alternatively, the providing the encapsulation cover 110 to cover the graphene bundle part 200 may comprise slipping the encapsulation cover 110 around the graphene bundle part 200. Because the encapsulation cover 110 should be tight, especially at the ends of the encapsulation cover 110, the enveloping the encapsulation cover 110 around the graphene bundle part 200 may be the preferable way to provide the encapsulation cover to cover the graphene bundle part 200. When the encapsulation cover 110 is provided by enveloping the encapsulation cover 110 around the graphene bundle part 200, the encapsulation cover 110 may be sealed with the adhesive tape after enveloping the encapsulation cover 110 around the graphene bundle part 200. Alternatively, when the encapsulation cover 110 is provided by slipping the encapsulation cover 110 around the graphene bundle part 200, the encapsulation cover 110 may be sealed with the adhesive tape before slipping the encapsulation cover 110 around the graphene bundle part 200. In all ways of providing the encapsulation cover 110 around the graphene bundle part 200, the encapsulation cover 110 is sealed with the adhesive tape before attaching the encapsulated graphene bundle part 200 to the end-fitting parts 120a, 120b. This enables that the adhesive tape enters the slots 410a, 410b of the end-fitting parts 120a, 120b together with the encapsulation cover 110 to enable that there are no un-sealed portions of the encapsulation cover 110. To form the encapsulation cover 110 a sheet of the encapsulating material may be cut into a desired shape depending on the shape of the graphene bundle part 200, before providing the encapsulation cover 110 to cover the graphene bundle part 200.

Before providing the encapsulation cover 110 around the graphene bundle part 200, at a step 520 the encapsulation cover 110 may be perforated to provide the plurality of ventilation holes 240 to the encapsulation cover 110 as discussed above. The plurality of ventilation holes 240 may be provided, e.g. formed, to the encapsulation cover 110 for example by a mechanical piercing or by a laser. In case one or more ventilation holes of the plurality of ventilation holes 240 comprises the filter structure 250, filter structure 250 may be formed by adding the filter material to the region on the encapsulation cover 110 around each ventilation hole 240 comprising the filter structure 250.

At a step 540, the first portion 230a of the graphene bundle part 200 is attached inside the first slot 410a of the first end-fitting part 120a and the second portion 230b of the graphene bundle part 200 is attached inside the second slot 410b of a second end-fitting part 120b with the sealing 430 so that the encapsulation cover 110 extends partly inside the first slot 410a of the first end-fitting part 120a and the second slot 410b of the second end-fitting part 120b. The first portion 230a of the graphene bundle part 200 and the second portion 230b of the graphene bundle part 200 are not in a direct contact with the respective end-fitting parts 120a, 120b due to the sealing 430. The sealing 430 is applied to the inside of slots 410a, 410b of the end-fitting parts 120a, 120b. The first end-fitting part 120a and the second end-fitting part 120b may be manufactured for example by machining. The first portion 230a of the graphene bundle part 200 protruding through the first slot 410a of the first end-fitting part 120a and the second portion 230b of the graphene bundle part 200 protruding through the second slot 410b of the second end-fitting part 120b form the thermal interfaces of the thermal strap 100 for connecting the thermal strap 100 to the terminals. The attaching step 540 may be performed by utilizing an assembly jig to ensure mechanical, geometrical, and structural accuracy of the attachment.

When the first end-fitting part 120a comprises the main part 440a and the secondary part 440b, the attaching of the first portion 230a of the graphene bundle part 200 inside the first slot 410a of the first end-fitting part 120a at the step 540 may comprise sandwiching the first portion 230a of the graphene bundle part 200 between the main part 440a and the secondary part 440b of the first end-fitting part 120a. Similarly, when the second end-fitting part 120b comprises the main part 470a and the secondary part 470b, the attaching of the second portion 230b of the graphene bundle part 200 inside the second slot 410b of the second end-fitting part 120b at the step 540 may comprise sandwiching the second portion 230b of the graphene bundle part 200 between the main part 470a and the secondary part 470b of the second end-fitting part 120b. The main part 440a and the secondary part 440b of the first end-fitting part 120a may be attached together with at least one first pin 460a, 460b having a respective alignment groove 450a, 450b residing partly in the main part 440a of the first end-fitting part 120b and partly in the secondary part 440b of the first end-fitting part 120a. Similarly, the main part 470a and the secondary part 470b of the second end-fitting part 120b may be attached together with at least one second pin 490a, 490b having a respective alignment groove 480a, 480b residing partly in the main part 470a of the second end-fitting part 120b and partly in the secondary part 470b of the second end-fitting part 120b. An adhesive may be added into the alignment grooves 450a, 450b, 480a, 480b to secure the placement of the pins 460a, 460b, 490a, 490b.

After the attachment step 540, the manufacturing method may further comprise a finishing stage at a step 550. The finishing stage may for example comprise setting, wherein the sealing 430 and the adhesive(s) are allowed to set; flattening and smoothing of the thermal and mechanical interface surfaces of the thermal strap 100; cleaning of the thermal strap 100, wherein the whole thermal strap 100 may be cleaned from particles, in particular from electrically conducting graphene sheet particles and/or adhesive particles; and/or packaging, wherein the thermal strap 100 may be packaged into a dust proof container ready for transfer the thermal strap 100 to its final assembly point. For example, the graphene sheets 220a-220n of the graphene bundle part 200 may protrude out from (i.e. outside) the slot(s) of the end-fitting part(s) 120a, 120b after attaching the graphene bundle part 200 to the end-fitting parts 120a, 120b, but the protruding parts of the graphene bundle part 200 may be cut and polished at the step 550 to form optimized thermal interfaces to the terminals. In other words, the manufacturing method enables also optimizing the thermal contact at the thermal interfaces of the thermal strap 100. The optimized thermal interfaces realized through the protruding parts of the graphene bundle part 200 ensure effective physical contact between the thermal interfaces of the thermal strap 100 and the terminals.

The thermal strap 100 and the method for manufacturing the thermal strap 100 described above enable optimal thermal properties (e.g. thermal conductance) with reduced weight and particle contamination while maintaining high flexibility of the thermal strap 100. The thermal strap 100 described above may be scaled individually for each application of the thermal strap 100 to achieve the optimal thermal properties and the reduced weight and particle contamination. For example, in the non-limiting detector application example of the thermal strap 100 mentioned above, the heat conductivity (@ 173 K) is measured to be 1.68±0.05 W/K.

The specific examples provided in the description given above should not be construed as limiting the applicability and/or the interpretation of the appended claims. Lists and groups of examples provided in the description given above are not exhaustive unless otherwise explicitly stated.

1. A thermal strap comprising:
a graphene bundle part comprising a stack of graphene sheets,
an encapsulation cover covering the graphene bundle part so that a first portion of the graphene bundle part and a second portion of the graphene bundle part protrude outside the encapsulation cover, and
a first end-fitting part comprising a first slot and a second end-fitting part comprising a second slot, wherein the first portion of the graphene bundle part is attached inside the first slot of the first end-fitting part and the second portion of the graphene bundle part is attached inside the second slot of the second end-fitting part with a sealing so that the encapsulation cover extends partly inside the first slot of the first end-fitting part and the second slot of the second end-fitting part.

2. The thermal strap according to claim 1, wherein the first portion of the graphene bundle part and the second portion of the graphene bundle part are at opposite ends of the graphene bundle part.

3. The thermal strap according to claim 1, wherein the first end-fitting part and the second end-fitting part each comprise a main part and a secondary part wherein the main part and the secondary part of the first end-fitting part define together the first slot of the first end-fitting part, and wherein the main part and the secondary part of the second end-fitting part define together the second slot of the second end-fitting part.

4. The thermal strap according to claim 3, wherein the first portion of the graphene bundle part is sandwiched between the main part and the secondary part of the first end-fitting part and the second portion of the graphene bundle part is sandwiched between the main part and the secondary part of the second end-fitting part.

5. The thermal strap according to claim 3, wherein the main part and the secondary part of the first end-fitting part are attached together with at least one first pin having a respective alignment groove located partly in the main part of the first end-fitting part and partly in the secondary part of the first end-fitting part, and wherein the main part and the secondary part of the second end-fitting part are attached together with at least one second pin having a respective alignment groove located partly in the main part of the second end-fitting part and partly in the secondary part of the second end-fitting part.

6. The thermal strap according to claim 1, wherein the encapsulation cover comprises a plurality of ventilation holes.

7. The thermal strap according to claim 6, wherein each of the plurality of ventilation holes comprises a filter structure.

8. The thermal strap according to claim 1, wherein the encapsulation cover is sealed with an adhesive tape.

9. The thermal strap according to claim 1, wherein the material of the sealing is thermally and/or electrically conductive.

10. The thermal strap according to claim 1, wherein the first portion of the graphene bundle part protruding through the first slot of the first end-fitting part and the second portion of the graphene bundle part protruding through the second slot of the second end-fitting part form thermal interfaces of the thermal strap.

11. A method for manufacturing a thermal strap the method comprising:
forming a graphene bundle part comprising a stack of graphene sheets,
providing an encapsulation cover to cover the graphene bundle part so that a first portion and a second portion of the graphene bundle part protrude outside the encapsulation cover, and
attaching the first portion of the graphene bundle part inside a first slot of a first end-fitting part and the second portion of the graphene bundle part inside a second slot of a second end-fitting part with a sealing so that the encapsulation cover extends partly inside the first slot of the first end-fitting part and the second slot of the second end-fitting part.

12. The method according to claim 11, wherein the providing the encapsulation cover to cover the graphene bundle part comprises enveloping the encapsulation cover around the graphene bundle part or slipping the encapsulation cover around the graphene bundle part.

13. The method according to claim 11, wherein the first portion of the graphene bundle part and the second portion of the graphene bundle part are at opposite ends of the graphene bundle part.

14. The method according to claim 11, wherein the first end-fitting part and the second end-fitting part comprise a main part and a secondary part wherein the main part and the secondary part of the first end-fitting part define together the first slot of the first end-fitting part, and wherein the main part and the secondary part of the second end-fitting part define together the second slot of the second end-fitting part.

15. The method according to claim 14, wherein the attaching of the first portion of the graphene bundle part inside the first slot of the first end-fitting part comprises sandwiching the first portion of the graphene bundle part between the main part and the secondary part of the first end-fitting part, and wherein the attaching of the second portion of the graphene bundle part inside the second slot of the second end-fitting part comprises sandwiching the second portion of the graphene bundle part between the main part and the secondary part of the second end-fitting part.

16. The method according to claim 14, wherein the method further comprises:
attaching the main part and the secondary part of the first end-fitting part together with at least one first pin having a respective alignment groove located partly in the main part of the first end-fitting part and partly in the secondary part of the first end-fitting part, and
attaching the main part and the secondary part of the second end-fitting part together with at least one second pin having a respective alignment groove located partly in the main part of the second end-fitting part and partly in the secondary part of the second end-fitting part.

17. The method according to claim 11, further comprising perforating the encapsulation cover to provide a plurality of ventilation holes.

18. The method according to claim 17, wherein each of the plurality of ventilation holes comprises a filter structure.

19. The method according to claim 11, further comprising sealing the encapsulation cover with an adhesive tape.

20. The method according to claim 11, wherein the material of the sealing is thermally and/or electrically conductive.

21. The method according to claim 11, wherein the first portion of the graphene bundle part protruding through the first slot of the first end-fitting part and the second portion of the graphene bundle part protruding through the second slot of the second end-fitting part form thermal interfaces of the thermal strap.
